(19) United States
(12) Patent Application Publication
(10) Pub. No.: US 2026/0304725 A1
(43) Pub. Date: Oct. 1, 2026

(54) COMPOSITE MAGNETIC SHEET

(71) Applicant: TOKIN CORPORATION, Shiroishi-shi, Miyagi (JP)

(72) Inventors: Toshiyuki IGARASHI, Sendai-shi (JP); Akiri URATA, Sendai-shi (JP); Miho CHIBA, Sendai-shi (JP)

(73) Assignee: TOKIN CORPORATION, Shiroishi-shi, Miyagi (JP)

(21) Appl. No.: 18/996,456

(22) PCT Filed: Jul. 26, 2023
(86) PCT No.: PCT/JP2023/027428

§ 371 Date: Jan. 17, 2025

(30) Foreign Application Priority Data
Jul. 28, 2022 (JP) 2022-120978

(51) Int. Cl. H05K 9/00; B22F 1/10; H01F 1/047; H01F 1/08

(52) U.S. Cl. CPC H05K 9/0083; B22F 1/10; H01F 1/047; H01F 1/083; B22F 2301/35

(57) ABSTRACT

A composite magnetic sheet includes a metal magnetic powder and a binder. The saturation magnetization of the composite magnetic sheet is 0.73 T to 1.20 T inclusive. The average thickness of the metal magnetic powder is between 0.1 μm to 3.0 μm inclusive. The average aspect ratio of the metal magnetic powder is 2 to 200 inclusive.

### TECHNICAL FIELD

This invention relates to a composite magnetic sheet.

### BACKGROUND ART

A composite magnetic sheet is also referred to as a noise suppression sheet. An example of the noise suppression sheet is disclosed in Patent Document 1. A near-field noise suppression sheet is designed to respond to magnetic field noise in a broad band of MHz to GHz. In detail, the near-field noise suppression sheet of Patent Document 1 includes a base member made of organic matter, flattened alloy powder supported by the base member, and a flame retardant dispersed in the base member.

### PRIOR ART DOCUMENTS

### Patent Document(s)

Patent Document 1: JPB6633037

### SUMMARY OF INVENTION

### Technical Problem

With the development of communications equipment and systems in recent years, there is a need to address electromagnetic noise in higher frequency bands. It is, therefore, an object of the present invention to provide a composite magnetic sheet that can respond to electromagnetic field noise in higher frequency bands.

### Solution to Problem

According to an aspect of the present invention, a composite magnetic sheet comprises magnetic metal powder and a binder. The saturation magnetization of the composite magnetic sheet is greater than or equal to 0.73 T and less than or equal to 1.20 T. The mean thickness of the magnetic metal powder is greater than or equal to 0.1 μm and less than or equal to 3.0 μm. The mean aspect ratio of the magnetic metal powder is greater than or equal to 2 and less than or equal to 200.

### Advantageous Effects of Invention

According to the present invention, the composite magnetic sheet has high saturation magnetization, and each alloy particle included therein has a thin thickness and a low aspect ratio. Accordingly, magnetic resonance appears at higher frequency bands, and the composite magnetic sheet can absorb electromagnetic noise of higher frequencies.

An appreciation of the objectives of the present invention and a more complete understanding of its structure may be had by studying the following description of the preferred embodiment and referring to the accompanying drawings.

### BRIEF DESCRIPTION OF DRAWINGS

FIG. 1 is a graph showing a typical frequency spectrum of a complex relative permeability imaginary part in a single particle of magnetic metal powder used in a composite magnetic sheet.

FIG. 2 is a diagram for describing the magnetization state of a flat particle.

FIG. 3 is a flowchart describing a composite magnetic sheet manufacturing method.

FIG. 4 is a graph showing a relationship between the particle size of nanocrystal powder of Comparative Example 1 and the number of times of milling processes.

FIG. 5 is a graph showing a relationship between the particle size of compound powder of Example 1 and the number of times of milling processes.

FIG. 6 shows a graph showing the nanocrystal powder's magnetization curve (Comparative Example 1) and a magnetization curve of the compound powder (Example 1).

FIG. 7 is a diagram showing an X-ray diffraction pattern of the nanocrystal powder (Comparative Example 1) that has not been subjected to a milling process.

FIG. 8 is a diagram showing an X-ray diffraction pattern of the compound powder (Example 1) that has not been subjected to a milling process.

FIG. 9 shows an X-ray diffraction pattern of the nanocrystal powder (Comparative Example 1) subjected to milling processes.

FIG. 10 is a diagram showing an X-ray diffraction pattern of the compound powder (Example 1) subjected to milling processes.

FIG. 11 is a graph showing a complex relative permeability spectrum of a composite magnetic sheet manufactured by using the nanocrystal powder (Comparative Example 1) and a complex relative permeability spectrum of a composite magnetic sheet manufactured by using the compound powder (Example 1).

FIG. 12 is a graph showing the complex relative permeability spectrum of a composite magnetic sheet manufactured using FeSiCr alloy powder (Comparative Example 2) and the composite magnetic sheet manufactured using the compound powder (Example 1).

FIG. 13 is a graph describing a half-width in a complex relative permeability spectrum (imaginary part).

FIG. 14 is a graph describing a half-width in a complex relative permeability spectrum (imaginary part) in the composite magnetic sheet manufactured using the compound powder of Example 1.

FIG. 15 shows a relationship between a particle shape and a peak frequency f_{C} of complex relative permeability spectrum (imaginary part) regarding magnetic metal powder in which saturation magnetization μ₀Mₛ is 1.70 T.

FIG. 16 shows a relationship between a particle shape and a peak frequency f_{C} of complex relative permeability spectrum (imaginary part) regarding magnetic metal powder in which saturation magnetization μ₀Mₛ is 1.80 T.

FIG. 17 shows a relationship between a particle shape and a peak frequency f_{C} of complex relative permeability spectrum (imaginary part) regarding magnetic metal powder in which saturation magnetization μ₀Mₛ is 1.90 T.

FIG. 18 shows a relationship between a particle shape and a peak frequency f_{C} of complex relative permeability spectrum (imaginary part) regarding magnetic metal powder in which saturation magnetization μ₀Mₛ is 2.15 T.

FIG. 19 shows a relationship between a particle shape and a peak frequency f_{C} of complex relative permeability spectrum (imaginary part) regarding magnetic metal powder in which saturation magnetization μ₀Mₛ is 2.35 T.

### DESCRIPTION OF EMBODIMENTS

While the invention may be realized in various modifications and alternative forms, specific embodiments are shown by example in the drawings and will be described in detail herein. It should be understood, however, that the drawings and detailed description thereto are not intended to limit the invention to the particular form disclosed, but on the contrary, the intention is to cover all modifications, equivalents, and alternatives falling within the spirit and scope of the present invention as defined by the appended claims.

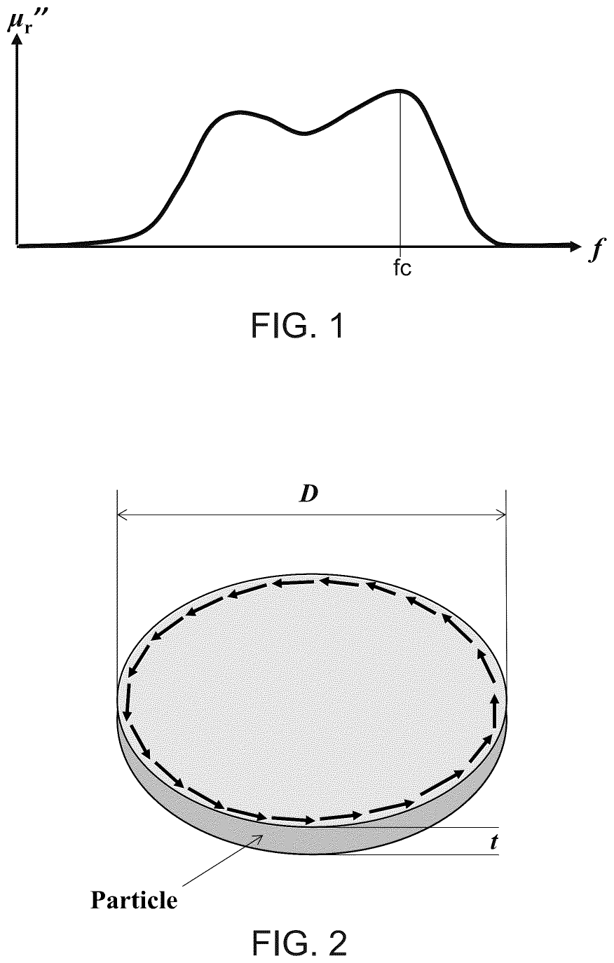

According to an embodiment of the present invention, a composite magnetic sheet includes at least magnetic metal powder and binder. A shape of the frequency spectrum of a relative permeability imaginary part μᵣ″, which relates to the noise suppression effect of the composite magnetic sheet, depends on a relative permeability imaginary part μᵣ″ of the magnetic metal powder included in the composite magnetic sheet. A typical frequency spectrum of the relative permeability imaginary part μᵣ″ of a single particle of the magnetic metal powder has two peaks, as shown in FIG. 1. By making a higher one of the two peaks or a higher-peak frequency f_{C} appear at a higher frequency side, the composite magnetic sheet can suppress or absorb electromagnetic noise of higher frequency bands.

As shown in FIG. 2, a magnetization state of a flat particle not applied with a magnetic field is closed in the periphery portion of the flat particle. Meanwhile, a natural frequency f_{C} of magnetic resonance according to the precession of each magnetization is represented by a mathematical formula 1. Here, saturation magnetization is represented by Mₛ (unit: A/m) in which vacuum permeability μ₀ is excepted.

$${f}_{C} = \frac{\vert γ \vert}{2 π} {M}_{s} \sqrt{{N}_{ρ} {N}_{z}} \qquad [ Formula 1 ]$$

where γ is a gyromagnetic ratio, Mₛ is saturation magnetization, Nₚ is a demagnetization factor in a radial direction of the flat particle, N_{z} a demagnetization factor in a vertical direction of the flat particle, and Nₚ+N_{z}=1.

As understood from formula 1, as a method for making a higher-peak frequency (a natural frequency) f_{C} appear at a higher frequency side, there is a method of increasing saturation magnetization μ₀Mₛ of magnetic metal powder and a method of increasing a demagnetization factor of the magnetic metal powder. The saturation magnetization μ₀Mₛ depends on the composition of the magnetic metal powder. On the other hand, the demagnetization factor depends on the shape of the magnetic metal powder. The present invention makes a higher-peak frequency f_{C} appear at a higher frequency side by using magnetic metal powder with higher saturation magnetization μ₀Mₛ as the magnetic metal powder and by setting each thickness of magnetic metal powder and aspect ratio of magnetic metal powder within a suitable range.

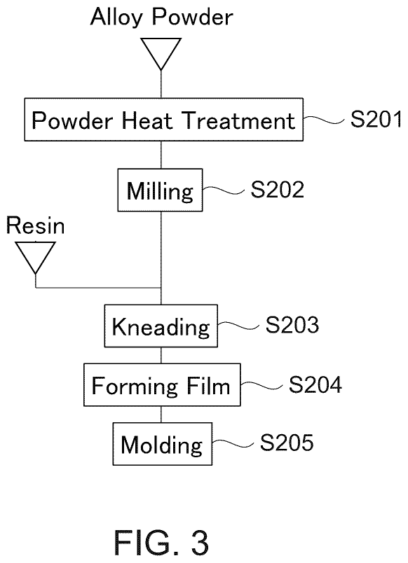

First, referring to FIG. 3, a description of the manufacturing method of the composite magnetic sheet will be briefly made according to the present embodiment. However, according to the present invention, the manufacturing method is not limited to the present embodiment but is susceptible of various modifications and alternative forms.

In the beginning, alloy powder obtained by an atomizing method is prepared as a starting material. It should be noted that the alloy powder has ferromagnetism. Next, a heat treatment is applied to the alloy powder (Step S201). Next, the alloy powder heat-treated is milled, or milling processes are applied to the alloy powder heat-treated so that flat particles are obtained (Step S202). Then, the flat particles are kneaded with resin as a binder (Step S203) to obtain a mixture. Next, the mixture forms a film on a base member (Step S204), and the film is dried to obtain a preliminary sheet. One or more preliminary sheets are molded to obtain a composite magnetic sheet (Step S205).

As understood from the aforementioned description, in the present embodiment, the magnetic metal powder included in the composite magnetic sheet consists of flat particles. In other words, in the present embodiment, the magnetic metal powder has an approximate disk shape. This shape is based on consideration of skin effect or skin depth. A higher-peak frequency f_{C} mainly depends on a demagnetization factor Nₚ in a radial direction in a magnetic metal powder with an approximate disk shape. Accordingly, to increase the higher-peak frequency f_{C}, the demagnetization factor Nₚ should be increased. Moreover, to increase the demagnetization factor Nₚ of the magnetic metal powder, an aspect ratio should be reduced. However, increasing the thickness of the magnetic metal powder is not preferable because of its relationship with the skin effect. Accordingly, a reduction of the aspect ratio is desired without increasing the thickness of the magnetic metal powder.

A description of the magnetic metal powder used in the composite magnetic sheet of the present embodiment will be made by using examples and comparative examples.

Alloy powder having a composition represented by Fe_{84.3}B_{6.0}Si_{0.5}P_{8.5}Cu_{0.7} was prepared by an atomizing method and heat-treated (Step S201) so that a compound was not formed, but a nanocrystal was formed. Thus, nanocrystal powder (hereinafter referred to as Comparative Example 1) was obtained. In addition, alloy powder obtained similarly to that obtained in Comparative Example 1 was heat-treated so that a compound was formed. Thus, compound powder (hereinafter as Example 1) was obtained. It should be noted that, in the present embodiment, “nanocrystal powder” means powder in which a crystal phase thereof consists of crystals with crystal structures of the body-centered cubic (BCC) structure. Moreover, in the present embodiment, “compound powder” means powder in which a crystal phase thereof includes crystals with crystal structures other than the BCC structure. Each “nanocrystal powder” and the “compound powder” may include an amorphous phase.

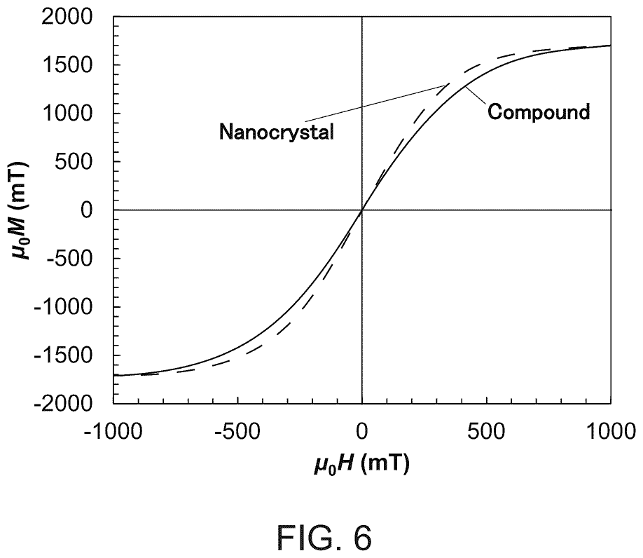

Magnetization curves of Comparative Example 1 obtained and Example 1 obtained were measured. The results are shown in FIG. 6 and Table 1.

TABLE 1

| | Comparative | |
|---|---|---|
| | Example 1 | Example 1 |
| | (Nanoclystal) | (Compound) |
| Saturation | 1704 | 1704 |
| Magnetization | | |
| μ₀Mₛ (mT) | | |
| Residual | 0.5601 | 7.773 |
| Magnetization | | |
| μ₀Mᵣ (mT) | | |
| Coersive Force | 0.1028 | 1.857 |
| (mT) | | |

As understood from FIG. 6 and Table 1, Example 1 was hard to be magnetized and had sizeable magnetic anisotropy compared to Comparative Example 1, which was confirmed between the magnetization curve of Comparative Example 1 and the magnetization curve of Example 1. Regarding saturation magnetization μ₀Mₛ, there was no difference between Comparative Example 1 and Example 1.

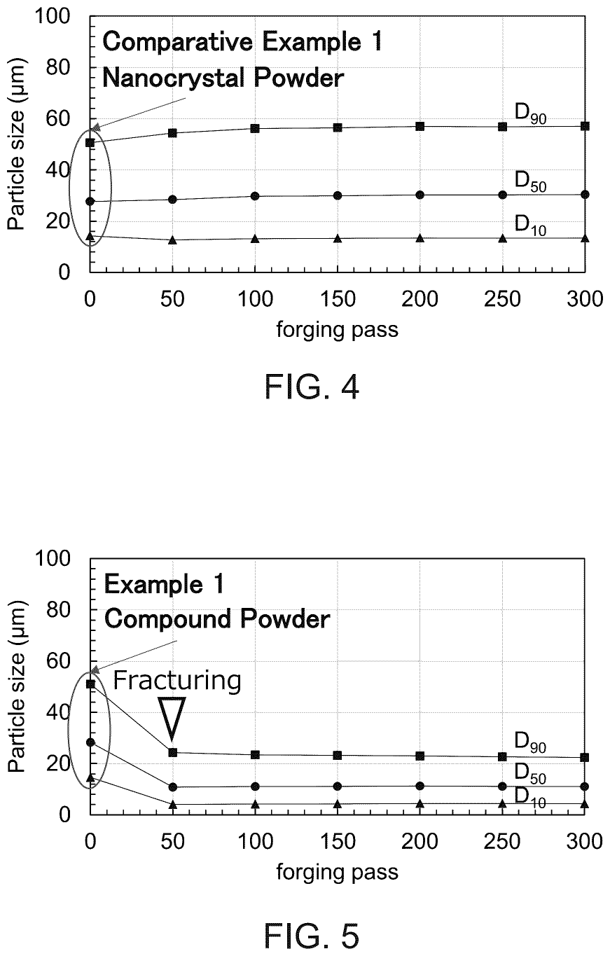

For each of Comparative Example 1 and Example 1, milling processes (Step S202) were repeatedly carried out, and particle diameters were measured. As shown in FIG. 4, even when the milling processes (Step S202) were repeated for Comparative Example 1, the particle diameter D was hardly changed. In contrast, when the milling processes were repeated for Example 1, the particle diameter D was gradually reduced, as shown in FIG. 5. However, regarding the compound powder, when the milling progressed to some extent, the particle diameter D hardly changed. Although the particle diameter D of the nanocrystal powder and the particle diameter D of the compound powder were approximately the same as each other before the milling processes, the particle diameter D of the compound powder was about one-third of the particle diameter D of the nanocrystal powder after the milling processes. Thus, Comparative Example 1 obtained powder with a mean thickness of 1 μm and a mean aspect ratio of 300, and Example 1 obtained powder with a mean thickness of 1 μm and a mean aspect ratio of 11. As just described, when the compound is formed in heat treatment (Step S201), a particle diameter can be reduced by following milling processes (Step S202). In other words, the compound powder can be reduced in a diameter of flat particles compared to nanocrystal powder. This is because the compound powder is brittler than the nanocrystal powder. A flat particle with a smaller diameter has a lower aspect ratio for the same thickness, so it can be expected to have a more prominent demagnetization factor, Nₚ.

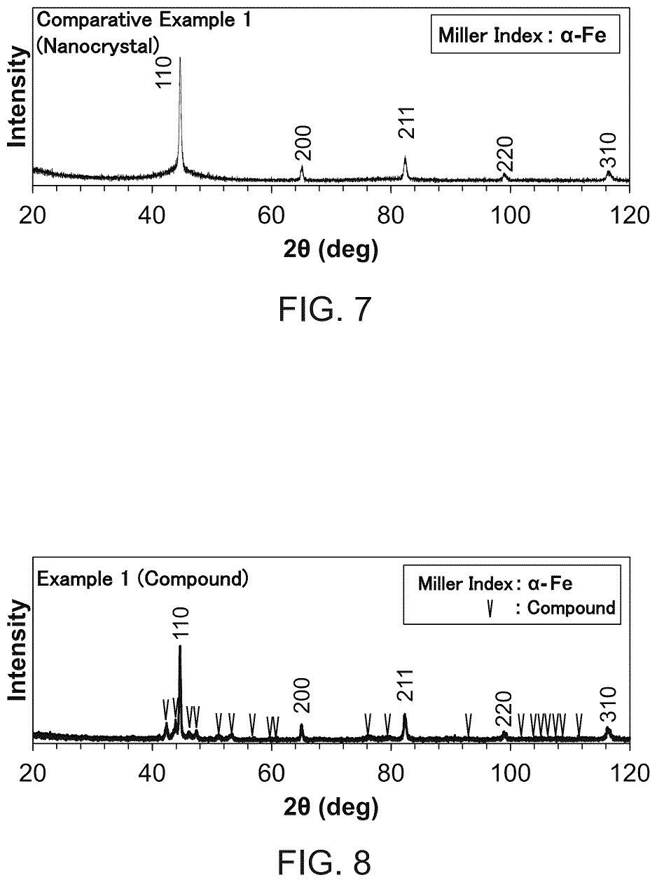

For each of Comparative Example 1 and Example 1, X-ray diffraction was carried out before and after the milling processes. A focusing method (Bragg-Brentano) was used as an X-ray diffraction method, and Cu was used as a ray source. The results are shown in FIGS. 7 to 10.

Referring to FIG. 7, an X-ray diffraction pattern of Comparative Example 1 before the milling processes has a plurality of noticeable peaks (mirror indexes are attached). Diffraction angles at which these peaks appear coincide with those at which peaks of a diffraction pattern of an α-Fe. Incidentally, the focusing method (Bragg-Brentano) measured the X-ray diffraction pattern using Cu as the ray source. The same is true for FIGS. 8 to 10.

Referring to FIG. 8, the X-ray diffraction pattern of Example 1 before the milling process has many small peaks (indicated by v) in addition to a plurality of noticeable peaks (mirror indexes are attached). Diffraction angles at which the noticeable peaks appear coincide with diffraction angles at which the peaks of the diffraction pattern of the α-Fe. On the other hand, the small peaks derive from the compound. From this, the nanocrystal powder and the compound powder are distinguishable from each other by comparing their X-ray diffraction patterns with each other.

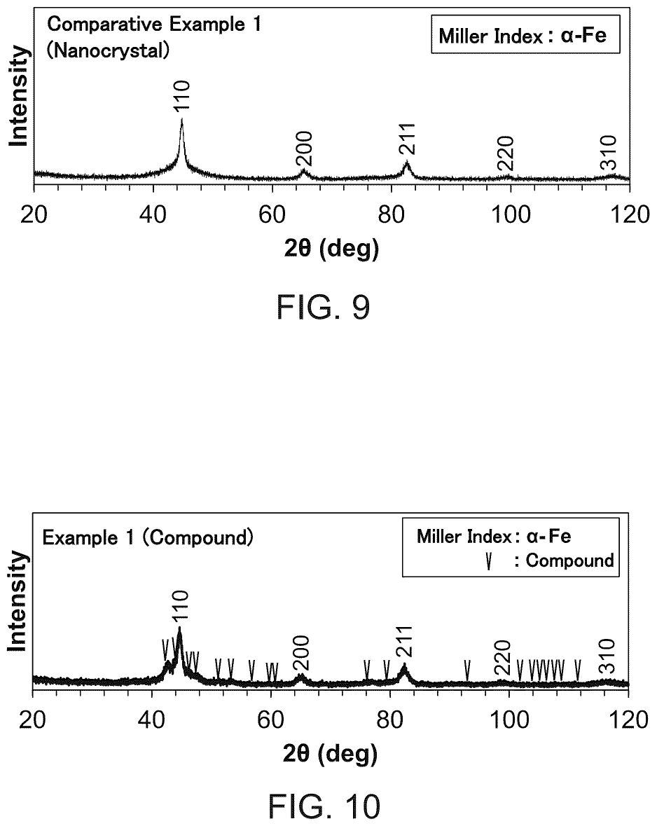

Referring to FIG. 9, in the X-ray diffraction pattern of Comparative Example 1 after the milling processes, although diffraction strength is reduced in comparison with that of FIG. 7, diffraction angles at which the peaks appear to coincide with those of FIG. 7. Similarly, in the X-ray diffraction pattern of Example 1 after the milling processes which is shown in FIG. 10, diffraction angles at which the peaks appear coincide with those of FIG. 8. Accordingly, Comparative Example 1 subjected to the milling processes and Example 1 subjected to the milling processes are distinguishable from each other by comparing their X-ray diffraction patterns with each other. Incidentally, in each of these flat particles, a longitudinal direction of a cross-section thereof has an in-plane orientation, and an incident X-ray scans a range of 10°≤θ≤60° provided that the plane has an angle θ=0°.

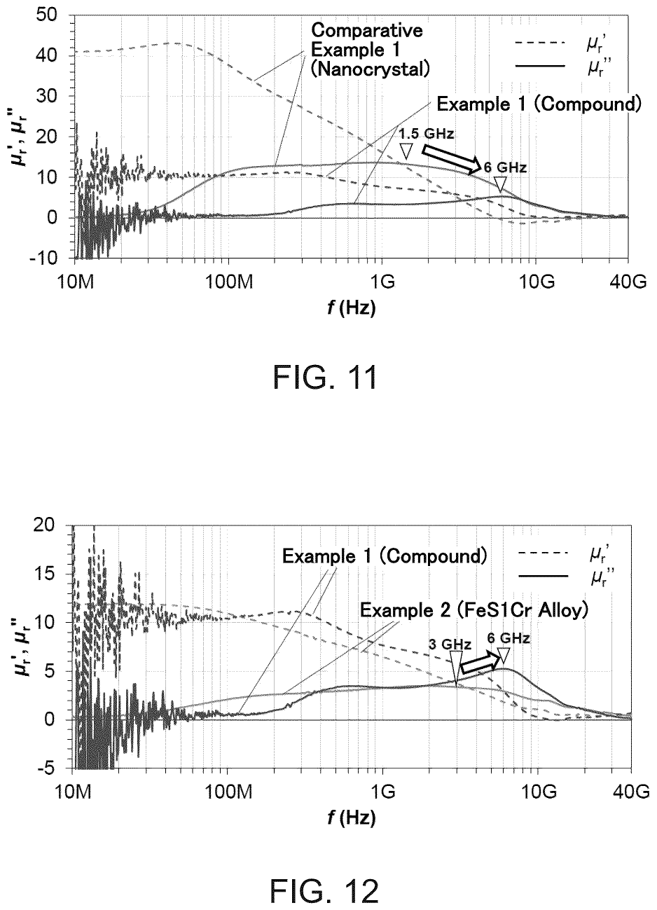

A composite magnetic sheet was made using Comparative Example 1, and the relative permeability thereof was measured. In addition, a composite magnetic sheet was made using Example 1, and relative permeability was measured. The measured results are shown in FIG. 11 and Table 2. Incidentally, saturation magnetization μ₀Mₛ of the composite magnetic sheet using Comparative Example 1 was equal to 0.816 T, and saturation magnetization μ₀Mₛ of the composite magnetic sheet using Example 1 was equal to 0.731 T. Furthermore, the relative permeability of a composite magnetic sheet which was made by using crystal powder consists of FeSiCr alloy (hereinafter referred to as Comparative Example 2) was measured. The measured results are shown in FIG. 12 and Table 3, together with the measured results of the composite magnetic sheet made using Example 1. Incidentally, the average aspect ratio of the crystal powder of Comparative Example 2 was equal to 1, and saturation magnetization μ₀Mₛ of the composite sheet using Comparative Example 2 was equal to 0.938 T.

TABLE 2

| | D₅₀ | d | μᵣ″ | | | | | |
|---|---|---|---|---|---|---|---|---|
| | (μm) | (g/cc) | 100 MHz | 700 MHz | 2.4 GHz | 5 GHz | 10 GHz | 28 GHz |
| Comparative | 30 | 4.1 | 11.4 | 13.5 | 12.2 | 8.6 | 3.0 | 0.4 |
| Example 1 | | (48 vol. %) | | | | | | |
| (Nanoclystal) | | | | | | | | |
| Example 1 | 11 | 3.7 | 0.4 | 3.5 | 3.7 | 5.0 | 3.3 | 0.5 |
| (Compound) | | (43 vol. %) | | | | | | |

TABLE 3

| | D₅₀ | d | μᵣ″ | | | | | |
|---|---|---|---|---|---|---|---|---|
| | (μm) | (g/cc) | 100 MHz | 700 MHz | 2.4 GHz | 5 GHz | 10 GHz | 28 GHz |
| Example 1 | 11 | 3.7 | 0.4 | 3.5 | 3.7 | 5.0 | 3.3 | 0.5 |
| (Compound) | | (43 vol. %) | | | | | | |
| Comparative | 5 | 4.5 | 2.1 | 3.1 | 3.4 | 3.1 | 2.0 | 0.7 |
| Example 2 | | (53 vol. %) | | | | | | |
| (FeSiCr) | | | | | | | | |

As understood from FIG. 11 and Table 2, a relative permeability imaginary part μᵣ″ of the composite magnetic sheet of Comparative Example 1 indicates high values at frequencies greater than or equal to several tens MHz. Accordingly, the composite magnetic sheet of Comparative Example 1 is suitable for noise suppression at high frequencies greater than or equal to several tens MHz. Incidentally, the relative permeability imaginary part μᵣ″ of the composite magnetic sheet of Comparative Example 1 has a higher-peak frequency f_{C} around 1.5 GHZ. Although the composite magnetic sheet of Comparative Example 1 is effective in suppressing noise from some tens MHz up to a high-frequency band, there is a possibility that necessary signals in a low-frequency band from 20 MHz to 200 MHz are reduced.

On the other hand, as understood from FIG. 11 and Table 2, the relative permeability imaginary part μᵣ″ of the composite magnetic sheet of Example 1 has a higher-peak frequency f_{C} around 6 GHZ. At frequencies higher than the higher-peak frequency f_{C}, the relative permeability imaginary part μᵣ″ of the composite magnetic sheet of Example 1 has values near those of the relative permeability imaginary part μᵣ″ of the composite magnetic sheet of Comparative Example 1. Accordingly, the composite magnetic sheet of Example 1 is suitable for noise suppression in a relatively high-frequency band (6 GHz or more). It is possible to absorb electromagnetic noise of the high-frequency band without interference with the necessary signals of the low-frequency band from 20 MHz to 200 MHz.

As understood from FIG. 12 and Table 3, the relative permeability imaginary part μᵣ″ of the composite magnetic sheet of Comparative Example 2 has a higher-peak frequency f_{C} around 3 GHZ. At frequencies higher than the higher-peak frequency f_{C}, the relative permeability imaginary part μᵣ″ of the composite magnetic sheet of Comparative Example 2 gently decreases with the frequency increase. When the frequency exceeds 10 GHZ, the relative permeability imaginary part μᵣ″ of the composite magnetic sheet of Comparative Example 2 has a value near the relative permeability imaginary part μᵣ″ of the composite magnetic sheet of Example 1. Accordingly, the composite magnetic sheet of Comparative Example 2 is suitable for noise suppression of the high-frequency band (10 GHz or more), similar to Example 1. However, the composite magnetic sheet of Comparative Example 2 is effective in suppressing noise of a high-frequency band from some tens MHz, so there is a possibility of reducing necessary signals in a wide range.

Here, suppressing noise in a higher desired frequency band, such as a 28 GHz band, will be considered. At this moment, no magnetic metal powder allows a higher-peak frequency f_{C} of a relative permeability imaginary part μᵣ″ of a composite magnetic sheet to be greater than or equal to 28 GHz. Accordingly, a half-width is introduced as a frequency range for sufficient noise suppression effect. In other words, it is considered to increase a frequency that gives a value equal to half of a higher-peak value in frequency characteristics of a relative permeability imaginary part μᵣ″ of a composite magnetic sheet to a desired frequency, for example, 28 GHz or more.

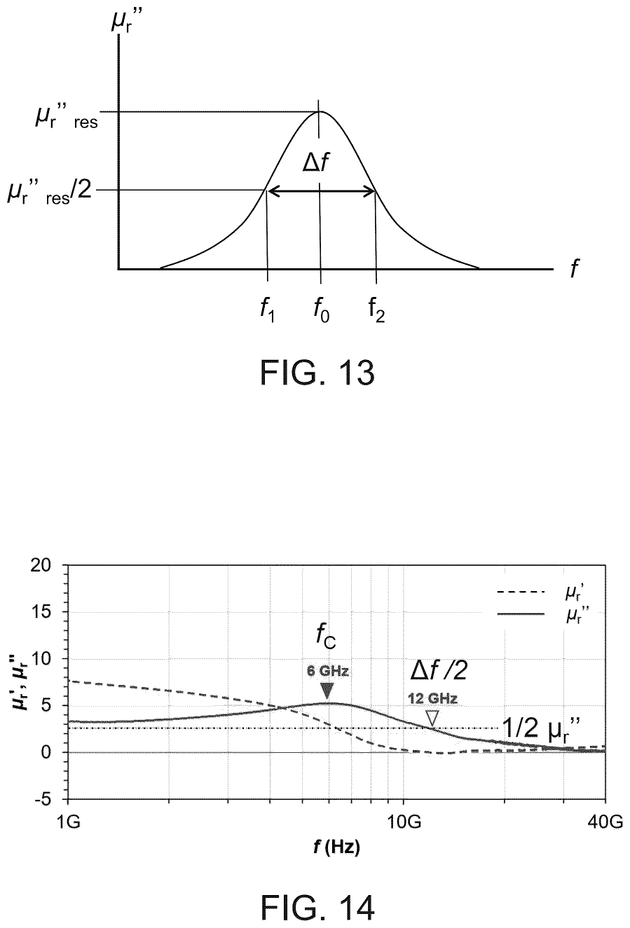

It is assumed that frequency characteristics of a relative permeability imaginary part μᵣ″ of a composite magnetic sheet show a single-peaked pattern in magnetic resonance, as shown in FIG. 13. In addition, it is assumed that a peak frequency thereof is equivalent to a higher-peak frequency f_{C} of the relative permeability imaginary part of the composite magnetic sheet. In FIG. 13, it is assumed that the value of the relative permeability imaginary part μᵣ″ is represented by μᵣ″=μᵣ″ᵣₑₛ when f_{C}=f₀. In addition, it is assumed that frequencies given μᵣ″=μᵣ″ᵣₑₛ/2 to the value “μᵣ” of the relative permeability imaginary part are represented by f₁ and f₂. A half-width Δf (=f₂−f₁) can be represented by Δf=2αf₀. Here, α is a damping factor and takes a value from 0.5 to 1.0 experientially. The f₂ (hereinafter a half value f₂) is represented by f₂=f₀+Δf/2 using Δf. It is made to try to increase this half-value frequency f₂ to a desired frequency, for example, 28 GHz or more.

In the Example of the composite magnetic sheet of Example 1, the higher-peak frequency f_{C} satisfies f_{C}=6 GHZ, so that f₂=f₀+Δf/2=12 GHZ provided that α=1. As understood from FIG. 14, the aforementioned assumptions match the actual measurement results. A half-value frequency f₂ in each of higher-peak frequencies 1 to 30 was found in each case of α=0.5 and α=1, and the results are shown in Table 4.

TABLE 4

| | f₂ (GHz) | f₂ (GHz) |
|---|---|---|
| f_{c} (GHz) | ※α = 0.5 | ※α = 1.0 |
| 1 | 1.5 | 2.0 |
| 2 | 3.0 | 4.0 |
| 3 | 4.5 | 6.0 |
| 4 | 6.0 | 8.0 |
| 5 | 7.5 | 10.0 |
| 10 | 15.0 | 20.0 |
| 15 | 22.5 | 30.0 |
| 20 | 30.0 | 40.0 |
| 25 | 37.5 | 50.0 |
| 30 | 45.0 | 60.0 |

As understood from Table 4, in the case of α=1, when f_{C}=5 GHz or more, noise of 10 GHz can be treated. Moreover, in the case of α=1, when f_{C}=15 GHZ or more, noise of 28 GHz can be treated. On the other hand, in the case of α=0.5, when f_{C}=10 GHz or more, noise of 15 GHz can be treated. Moreover, in the case of α=0.5, when f_{C}=20 GHz or more, noise of 28 GHz can be treated.

Next, the description will be made about a relationship between a higher-peak frequency f_{C} of a relative permeability imaginary part μᵣ″ of magnetic metal powder and the thickness and aspect ratio.

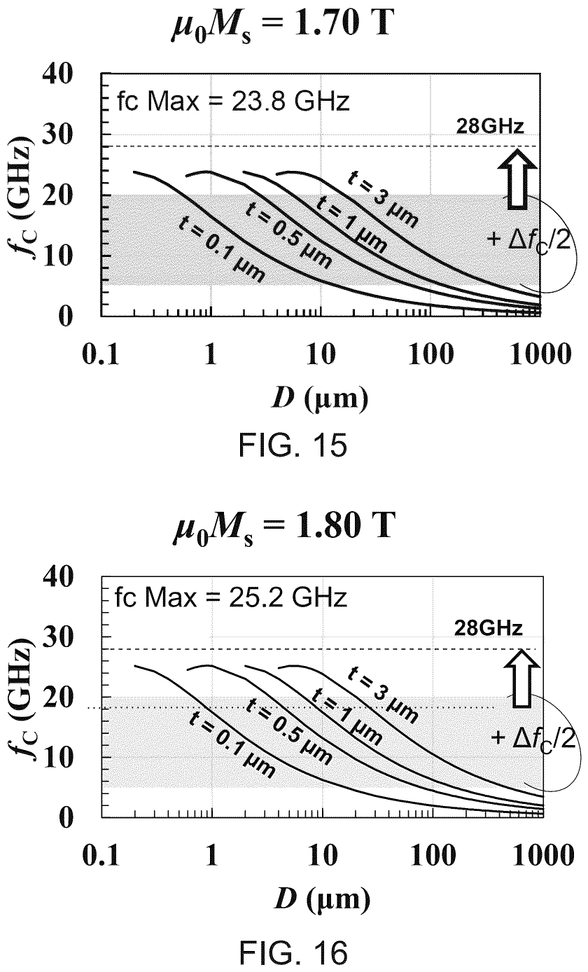

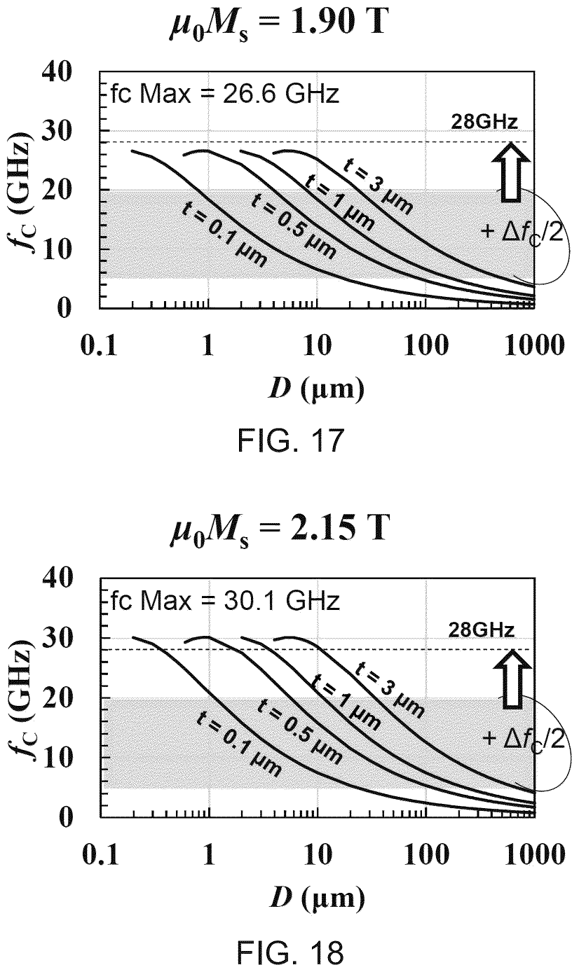

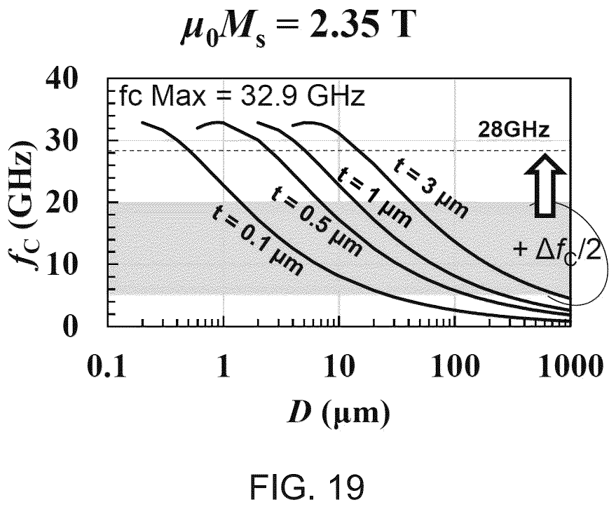

As understood from each of FIGS. 15 to 19, when the thickness t of the magnetic metal powder is fixed, the higher-peak frequency f_{C} of the relative permeability imaginary part μᵣ″ of the magnetic metal powder increases as the diameter D of the magnetic metal powder decreases. Moreover, when the diameter D of the magnetic metal powder is fixed, the higher-peak frequency f_{C} increases as the thickness t of the magnetic metal powder increases. Thus, it can be said that the higher-peak frequency f_{C} increases as the aspect ratio of the magnetic metal powder decreases.

Furthermore, as understood from FIGS. 15 to 19, when the aspect ratio of the magnetic metal powder is fixed, it can be said that the higher-peak frequency f_{C} increases as saturation magnetization μ₀Mₛ increases.

In each of FIGS. 15 to 19, if the higher-peak frequency f_{C} is in a range depicted by a gray tone, the half frequency f₂ reaches 10 GHZ (α=0.5) to 30 GHZ (α=1.0). Accordingly, although it depends on the value of a when the higher-peak frequency f_{C} is greater than or equal to 15 GHZ, the composite magnetic sheet using the magnetic metal powder can treat noise of 28 GHz.

In the present embodiment, the magnetic metal powder has a principal material of Fe. The use of Fe as the principal material can achieve high saturation magnetization. For example, the magnetic metal powder may be pure iron (α-Fe). The saturation magnetization μ₀Mₛ of the pure iron is equal to 2.15 T. Alternatively, the magnetic metal powder may be permendur (Fe-49Co-2V). The saturation magnetization μ₀Mₛ of the permendur is equal to 2.35 T.

In the present embodiment, the magnetic metal powder may be an alloy composition made of a principal component having a principal material of Fe and inevitable impurities. Here, the principal component of the magnetic metal powder is a metal alloy represented by a composition formula of FeₐM_{w}Cu_{z}. M combines two or more B, Si, P, and C. In particular, M should contain B and P. P to form compounds and B to embrittle magnetic metal powder. In the aforementioned composition formula, a=100−w−z, 0<w≤25 at % and 0≤z≤2 at %. When compounds are formed therein, these alloy compounds show higher embrittlement than pure iron or permendur. Accordingly, regarding the alloy compound, it is easy to reduce a particle diameter thereof, and it is easy to reduce an aspect ratio without increasing a thickness t thereof. As a result, in a frequency band higher than the higher-peak frequency f_{C}, for example, 10 GHz or more, high relative permeability imaginary part μᵣ″ can be achieved.

In the present embodiment, the magnetic metal powder's principal component may be represented by a composition formula of FeₐB_{b}Si_{c}PₓC_{y}Cu_{z}. Here, 80≤a≤95 at %, 1≤b≤20 at %, 0≤c≤10 at %, 1≤x≤20 at %, 0≤y≤5 at % and 0.4≤z≤1.4 at %. Fe should be greater than or equal to 80 at % because high saturation magnetization is obtained, and Fe is less than or equal to 95 at % because of the contribution to embrittlement of the magnetic metal powder and to the reduction of the fusing point of the magnetic metal powder. B should be greater than or equal to 1 at % because of its contribution to embrittlement of the magnetic metal powder, and B is less than or equal to 20 at % because of suppressing a decrease of the saturation magnetization. Si should be less than or equal to 10 at % because of suppressing a decrease of the saturation magnetization. P should be greater than or equal to 1 at % because of the contribution to embrittlement of the magnetic metal powder, and P is less than or equal to 20 at % because of suppressing a decrease of the saturation magnetization. C should be less than or equal to 5 at % because of suppressing a decrease of the saturation magnetization and deterioration of magnetic characteristics. It is preferable that Cu is greater than or equal to 0.4 at % because of contribution to embrittlement of the magnetic metal powder and to increment of the saturation magnetization caused by forming homogenous nanocrystals and that Cu is less than or equal to 1.4 at % because of suppressing deterioration of the magnetic characteristics. Using the magnetic metal powder with the aforementioned composition, the saturation magnetization of the magnetic metal powder of 1.70 T or more can be obtained.

In the present embodiment, a part of Fe in the principal composition of the magnetic metal powder may be replaced by one or more elements selected from Al, Ti, Mn, S, O, N, Ca, V, Zr, Hf, Nb, Ta, Mo, W, Cr, Co, Ni, Ag, Zn, Ga, Ge, In, Sn, As, Sb, Bi, Y and rare earth elements at 3 at % or less. Alternatively, in the present embodiment, a part of Fe in the principal composition of the magnetic metal powder may be replaced by at least one of Co and Ni at 40 at % or less. Co and Ni are elements that provide magnetism and serve to increase saturation magnetization.

In the present embodiment, the crystal structure of the magnetic metal powder may not be single. In other words, the magnetic metal powder of the present embodiment may be a mixed crystal, including two or more crystal structures. In the present embodiment, one of the crystal structures is a body-centered cubic structure containing Fe. Moreover, the magnetic metal powder of the present embodiment may include an amorphous phase.

In the present embodiment, the saturation magnetization μ₀Mₛ of the magnetic metal powder is greater than or equal to 1.70 T and less than or equal to 2.35 T. Moreover, the coercive force of the magnetic metal powder is greater than or equal to 1 mT. This is for achieving a desired noise suppression effect in a high-frequency band, for example, a band of 28 GHz.

In the present embodiment, by producing a composite magnetic sheet by using the magnetic metal powder having a high saturation magnetization μ₀Mₛ as mentioned above and macromolecular acrylic polymer (molecular weight M_{w}≥800,000) as a binder, a composite magnetic sheet having a high saturation magnetization μ₀Mₛ can be obtained. Incidentally, in the present embodiment, the density of the composite magnetic sheet may be greater than or equal to 3.7 g/cm³. In other words, the composite magnetic sheet of the present embodiment can obtain the high saturation magnetization μ₀Mₛ even if it has a relatively low density.

In the present embodiment, the saturation magnetization μ₀Mₛ of the composite magnetic sheet is greater than or equal to 0.73 T and less than or equal to 1.20 T. For example, when the composite magnetic sheet contains 43 vol. % of the magnetic metal powder having the saturation magnetization of 1.70 T, the saturation magnetization μ₀Mₛ thereof is equal to 0.73 T. Alternatively, when the composite magnetic sheet contains 51 vol. % of the magnetic metal powder having the saturation magnetization of 2.35 T, the saturation magnetization μ₀Mₛ thereof is equal to 1.20 T. The saturation magnetization μ₀Mₛ of the composite magnetic sheet is preferably greater than or equal to 0.73 T and less than or equal to 0.97 T. This is because, even at some sacrifice of the saturation magnetization μ₀Mₛ, it is adequate to reduce an aspect ratio for increasing relative permeability imaginary part μᵣ″ of the magnetic metal powder at a high frequency band. For example, when the sheet contains 51 vol. % of the magnetic metal powder containing 90 at % Fe and having the saturation magnetization μ₀Mₛ of 1.9 T, the saturation magnetization is equal to 0.97 T.

In order to obtain the aforementioned saturation magnetization μ₀Mₛ, the magnetic metal powder is subjected to milling processes so that a mean thickness is greater than or equal to 0.1 μm and less than or equal to 3.0 μm and that a mean aspect ratio is greater than or equal to 2 and less than or equal to 200. The mean thickness of the magnetic metal powder is preferably greater than or equal to 0.1 μm and less than or equal to 1.0 μm, and the mean aspect ratio is preferably greater than or equal to 2 and less than or equal to 20. This is because, though the aspect ratio is preferable to be lower, it becomes hard to orient the magnetic metal powder in the composite magnetic sheet when it becomes under 2. In addition, this is because desired characteristics cannot be obtained when the aspect ratio exceeds 200. When the aspect ratio is less than or equal to 20, the relative permeability imaginary part μᵣ″ is equal to half of the higher-frequency peak value or more at a frequency of 28 GHz.

As described above, the composite magnetic sheet of the present embodiment can suppress higher frequency noise, e.g., noise in the 28 GHz band, by using magnetic metal powder having higher saturation magnetization μ₀Mₛ as magnetic metal powder and setting each of a thickness of the magnetic metal powder and an aspect ratio of the magnetic metal powder to an appropriate range.

Although the specific explanation about the present invention is made above concerning concrete embodiments, the present invention is not limited thereto but susceptible to various modifications and alternative forms without departing from the spirit of the invention.

For example, the magnetic metal powder may be provided with an oxide layer or a nitride layer on a surface thereof. This is to increase electrical resistance. Increasing the electrical resistance, a noise suppression sheet can be used for a relatively high-voltage part of an electronic device. In other words, the application range of the noise suppression sheet can be expanded.

This application is based on a Japanese Patent Application of JP2022-120978 filed with the Japanese Patent Office on Jul. 28, 2022, incorporated herein in their entirety by reference.

While what is believed to be the preferred embodiment of the invention has been described, those skilled in the art will recognize that other and further modifications may be made without departing from the spirit of the invention. It is intended to claim all such embodiments that fall within the true scope of the invention.

1. A composite magnetic sheet comprising magnetic metal powder and a binder; wherein:
saturation magnetization of the composite magnetic sheet is greater than or equal to 0.73 T and less than or equal to 1.20 T;
a mean thickness of the magnetic metal powder is greater than or equal to 0.1 μm and less than or equal to 3.0 μm; and
a mean aspect ratio of the magnetic metal powder is greater than or equal to 2 and less than or equal to 200.

2. The composite magnetic sheet as recited in claim 1, wherein a density is greater than or equal to 3.7 g/cm³.

3. The composite magnetic sheet as recited in claim 1, wherein the saturation magnetization is greater than or equal to 0.73 T and less than or equal to 0.97 T.

4. The composite magnetic sheet as recited in claim 1, wherein:
the mean thickness is greater than or equal to 0.1 μm and less than or equal to 1.0 μm; and
the mean aspect ratio is greater than or equal to 2 and less than or equal to 20.

5. The composite magnetic sheet as recited in claim 1, wherein a coercive force of the magnetic metal powder is greater than or equal to 1 mT.

6. The composite magnetic sheet as recited in claim 5, wherein a phase structure of the magnetic metal powder comprises a mixed crystal of two or more crystal structures which includes a crystal structure of a body-centered cubic lattice containing Fe and another crystal structure.

7. The composite magnetic sheet as recited in claim 6, wherein:
the magnetic metal powder comprises an alloy composition comprising a principal component having a principal material of Fe and inevitable imparities; and
the principal component is represented by a composition formula of FeaMwCuz; where M is a combination at least two of B, Si, P and C, and a=100−w−z, 0<w≤25 at % and 0≤z≤2 at %.

8. The composite magnetic sheet as recited in claim 1, wherein the saturation magnetization of the magnetic metal powder is greater than or equal to 1.70 T and less than or equal to 2.35 T.

9. The composite magnetic sheet as recited in claim 8, wherein:
the magnetic metal powder comprises an alloy composition comprising a principal component having a principal material of Fe and inevitable imparities; and
the principal component is represented by a composition formula of FeaBbSicPxCyCuz; where 80≤a≤95 at %, 1≤b≤20 at %, 0≤c≤10 at %, 1≤x≤20 at %, 0≤y≤5 at % and 0.4≤z≤1.4 at %.

10. The composite magnetic sheet as recited in claim 9, wherein a part of Fe may be replaced by one or more elements selected from Al, Ti, Mn, S, O, N, Ca, V, Zr, Hf, Nb, Ta, Mo, W, Cr, Co, Ni, Ag, Zn, Ga, Ge, In, Sn, As, Sb, Bi, Y and rare earth elements at 3 at % or less.

11. The composite magnetic sheet as recited in claim 9, wherein a part of Fe may be replaced by at least one of Co and Ni at 40 at % or less.
